(19) United States
(12) Patent Application Publication
(10) Pub. No.: US 2015/0225645 A1
(43) Pub. Date: Aug. 13, 2015

(54) ETCHING LIQUID, ETCHING METHOD USING THE SAME, AND METHOD OF PRODUCING SEMICONDUCTOR DEVICE

(71) Applicant: FUJIFILM Corporation, Tokyo (JP)

(72) Inventors: Tetsuya KAMIMURA, Haibara-gun (JP); Kee Young PARK, Haibara-gun (JP); Naotsugu MURO, Haibara-gun (JP); Tadashi INABA, Haibara-gun (JP)

(73) Assignee: FUJIFILM Corporation, Tokyo (JP)

(21) Appl. No.: 14/692,106

(22) Filed: Apr. 21, 2015

Related U.S. Application Data
(63) Continuation of application No. PCT/JP2013/077800, filed on Oct. 11, 2013.

(30) Foreign Application Priority Data
Oct. 22, 2012 (JP) 2012-233290

(51) Int. Cl. C09K 13/08; H01L 21/306

(52) U.S. Cl. CPC C09K 13/08; H01L 21/30608

(57) ABSTRACT

An etching liquid for processing a substrate having a first layer containing titanium nitride (TiN) and a second layer containing at least one metal selected from transition metals belonging to group 3 to group 11 of the periodic table thereby removing the first layer selectively, wherein the etching liquid contains a hexafluorosilicic acid compound, and an oxidizing agent of which concentration is 0.05% by mass or more and less than 10% by mass.

### CROSS-REFERENCE TO RELATED APPLICATIONS

This application is a continuation of PCT/JP2013/077800 filed on Oct. 11, 2013 which claims benefit of Japanese Patent Application No. 2012-233290 filed on Oct. 22, 2012, the subject matters of which are incorporated herein by reference in their entirety.

### TECHNICAL FIELD

The present invention relates to an etching liquid for a semiconductor substrate, an etching method using the same, and a method of producing a semiconductor device.

### BACKGROUND ART

Miniaturization and diversification of semiconductor devices have progressed more and more, and a processing method thereof covers a wide range with respect to each of device structures and production steps. As regards etching of the substrate, development of both dry etching and wet etching has been advanced, and a variety of chemical liquids and processing conditions have been proposed depending on kinds and structures of the substrate material.

Above all, when a device structure of CMOS, DRAM or the like is produced, a technique of etching a prescribed material precisely is important and as one of techniques of addressing such problem, a wet etching which utilizes a chemical liquid is exemplified. For example, a precise etching processing is required in the production of circuit wiring of a microscopic transistor circuit, a metal electrode material, or a substrate having a barrier layer, a hard mask, and the like. However, sufficient study has not yet been done on etching conditions and chemical liquids suitable for each of the substrates containing a wide variety of metal compounds. Under these circumstances, an efficient removal of a hard mask or the like applied to the device substrate has been laid out as a production problem. Specifically, there are examples of studies on chemical liquids for etching titanium nitride (TiN) (see Patent Literatures 1 to 5).

### CITATION LIST

### Patent Literatures

Patent Literature 1: JP-A-01-272785 (“JP-A” means unexamined published Japanese patent application)
Patent Literature 2: JP-A-55-20390
Patent Literature 3: U.S. Pat. No. 3,514,407
Patent Literature 4: U.S. Pat. No. 3,850,712
Patent Literature 5: JP-A-2005-097715

### SUMMARY OF INVENTION

### Technical Problem

By the way, in recent semiconductor device production, there is a requirement for a processing technique of wet-etching a metal hard mask (MHM) composed of TiN under the condition of exposed contact plug composed of tungsten (W), copper (Cu) and the like. In the production, a solid hard mask composed of TiN has to be removed without damaging the contact plug composed of metals. That is to say, simply developing of chemical liquids having removal performance for TiN is not enough to respond to such a requirement. In particular, recently the contact plug has increasingly been miniaturized and it still more increases the difficulty of a fine and selective etching using chemical liquids.

In view of the above, the present invention addresses the provision of an etching liquid which removes a first layer containing TiN selectively and efficiently to a second layer containing a particular metal, an etching method using the etching liquid, and a method of producing a semiconductor device.

### Solution to Problem

The above problems can be solved by the following means.

[1] An etching liquid for processing a substrate having a first layer containing titanium nitride (TiN) and a second layer containing at least one metal selected from transition metals belonging to group 3 to group 11 of the periodic table thereby removing the first layer selectively, wherein the etching liquid contains a hexafluorosilicic acid compound, and an oxidizing agent of which concentration is 0.05% by mass or more and less than 10% by mass.
[2] The etching liquid described in the item [1], wherein the second layer has at least one metal selected from Co, Ni, Cu, Ag, Ta, Hf, W, Pt and Au.
[3] The etching liquid described in the item [1] or [2], wherein the hexafluorosilicic acid compound is selected from hexafluorosilicic acid, ammonium hexafluorosilicate, and potassium hexafluorosilicate.
[4] The etching liquid described in any one of the items [1] to [3], wherein the oxidizing agent is nitric acid or hydrogen peroxide.
[5] The etching liquid described in any one of the items [1] to [4], wherein a rate ratio (R1/R2) of an etching rate (R1) of the first layer and an etching rate (R2) of the second layer is 2 or more.
[6] The etching liquid described in any one of the items [1] to [5], further containing an anticorrosive agent for the second layer.
[7] The etching liquid described in the item [6], wherein the anticorrosive agent is composed of a compound represented by any one of the following formulae (I) to (IX):

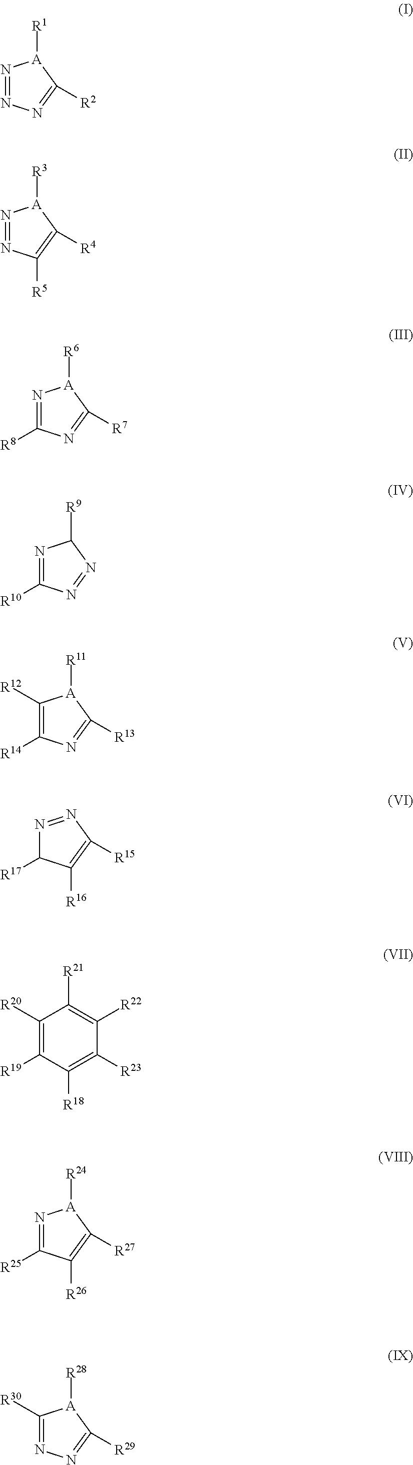

wherein R¹ to R³⁰ each independently represent a hydrogen atom or a substrate; in this case, neighbors adjacent to each other may be ring-fused to form a cyclic structure; A represents a hetero atom with the proviso that when A is divalent, there exists none of R¹, R³, R⁶, R¹¹, R²⁴ and R²⁸, by which A is each substituted.

[8] The etching liquid described in the item [6] or [7], wherein the anticorrosive agent is contained in a range of from 0.01 to 10% by mass.
[9] The etching liquid described in any one of the items [1] to [8], wherein a pH is from −1 to 5.
[10] An etching method comprising, at the time of processing a substrate having a first layer containing titanium nitride (TiN) and a second layer containing at least one metal selected from transition metals belonging to group 3 to group 11 of the periodic table, processing by applying an etching liquid containing a hexafluorosilicic acid compound, and an oxidizing agent of which concentration is 0.05% by mass or more and less than 10% by mass, to the substrate.
[11] The etching method described in the item [10], wherein the second layer has at least one metal selected from Co, Ni, Cu, Ag, Ta, Hf, W, Pt and Au.
[12] The etching method described in the item [10] or [11], wherein the substrate further has a third layer containing at least one metal compound selected from the group consisting of SiO, SiN, SiOC and SiON.

[13] The etching method described in the item [12], wherein the first layer containing titanium nitride (TiN) is layered on the upper part than the third layer in order to protect the third layer.

[14] The etching method described in any one of the items [10] to [13], wherein the method of applying the etching liquid to the substrate contains a step of supplying the etching liquid onto the substrate from above the substrate while rotating the substrate.
[15] The etching method described in the item [14], further supplying chemical liquids while moving a discharge opening of the etching liquid for supply, in motion relative to the upper surface of the rotating semiconductor substrate.
[16] The etching method described in any one of the items [10] to [15], wherein the processing by the etching liquid is carried out after processing of the second layer and/or the third layer by a dry etching process.
[17] A method of producing a semiconductor device comprising: removing a first layer containing titanium nitride (TiN) by the etching method described in any one of the items [10] to [16]; and then producing the semiconductor device from the remaining substrate.

### Advantageous Effects of Invention

By the etching liquid and the etching method, and the method of producing a semiconductor device using the same according to the present invention, a first layer containing TiN can be removed selectively and efficiently to a second layer containing a particular metal. In addition, by the present invention, point defect generation can be prevented if necessary, so that good in-plane uniformity in etching can be realized.

Other and further features and advantages of the invention will appear more fully from the following description, appropriately referring to the accompanying drawings.

### BRIEF DESCRIPTION OF DRAWINGS

FIG. 1 is a section view diagrammatically showing an example of a production step of a semiconductor substrate (before etching) according to one embodiment of the present invention.

FIG. 2 is a section view diagrammatically showing an example of a production step of a semiconductor substrate (after etching) according to one embodiment of the present invention.

FIG. 3 is a configuration diagram showing a part of the wet-etching equipment according to a preferable embodiment of the present invention.

FIG. 4 is a top view diagrammatically showing moving-track-line of the nozzle with respect to the semiconductor substrate according to one embodiment of the present invention.

### DESCRIPTION OF EMBODIMENTS

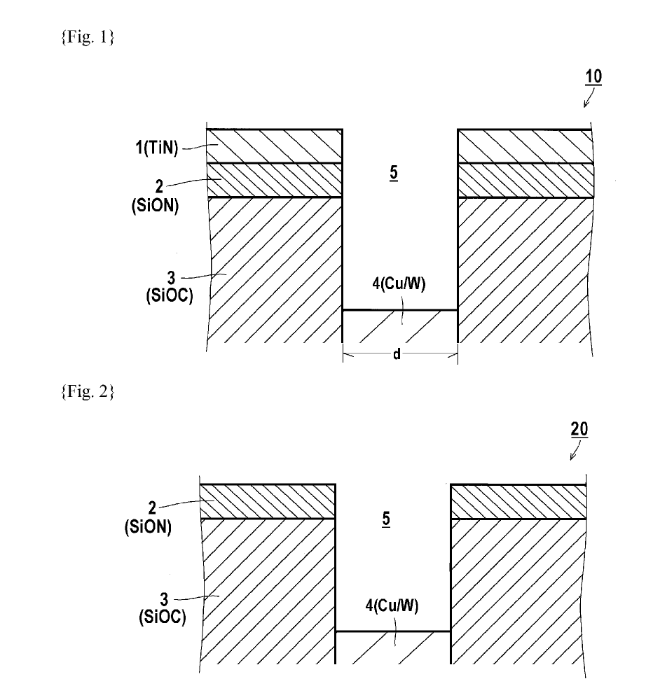

First, preferable embodiments of the etching step concerning the etching method of the present invention are explained on the basis of FIG. 1 and FIG. 2.

### [Etching Process]

FIG. 1 is a view showing a semiconductor substrate before etching. In the production example of the present embodiment, a layered product is used, in which SiOC layer 3 and SiON layer 2 as a specific third layer are disposed on a silicon wafer (not shown) and TiN layer 1 is formed on the third layer. At this time, via 5 has been formed already in the above-described composite layer and, a second layer (metal layer) 4 containing a metal has been formed at the bottom of via 5. Onto substrate 10 at this state, an etching liquid (not shown) according to the present embodiment is applied to remove the TiN layer. As a result, substrate 20 having a configuration in which the TiN film has been removed as shown in FIG. 2 can be obtained. Needless to say, although the etching as graphically shown is ideal in the present invention and a preferable embodiment thereof, a remainder of the TiN layer or alternatively some corrosion of the second layer is appropriately acceptable according to a required quality of a semiconductor device to be produced and the like and, therefore, the present invention is not construed to a limited extent by the above description.

Note that, when a silicon substrate or a semiconductor substrate, or simply a substrate is mentioned, these are used in the sense of including not only a silicon wafer but also a whole substrate structure provided with a circuit structure. The term “the element of the substrate” refers to an element that constitutes the silicon substrate that is defined above, and may be made of a single material or a plurality of materials. A processed semiconductor substrate is sometimes called as a semiconductor substrate product by a distinction. A tip or a processed product thereof, which has been obtained by further processing the semiconductor substrate, if needed, and then by singulating the same is referred to as semiconductor device or semiconductor equipment. With respect to the direction of the semiconductor, in reference to FIG. 1, the opposite side to the silicon wafer (TiN side) is called as “upper”, or “head edge”, while the silicon wafer side (SiOC side) is called as “under”, or “bottom”.

### [Etching Liquid]

Next, a preferable embodiment of the etching liquid of the present invention is explained. The etching liquid of the present embodiment contains a hexafluorosilicic acid compound and a particular amount of an oxidizing agent. Hereinafter, each of components including optional ones is explained.

### (Oxidizing Agent)

Examples of the oxidizing agent include nitric acid, hydrogen peroxide, ammonium persulfate, perboric acid, peracetic acid, periodic acid, perchloric acid, or a combination thereof. Among them, nitric acid or hydrogen peroxide is particularly preferable.

The oxidizing agent is contained in an amount of 0.05% by mass or more, preferably in an amount of 0.1% by mass or more, and more preferably in an amount of 0.3% by mass or more, with respect to the total amount of the etching liquid of the present embodiment. The upper limit thereof is less than 10% by mass, preferably 9.5% by mass or less, more preferably 7.5% by mass or less, still more preferably 5% by mass or less, and particularly preferably 3% by mass or less. Setting to the above-described upper limit or less is preferable from the viewpoint that good protection performance (selective etching) of the second layer can be achieved thereby. By setting to the above-described lower limit or greater, sufficient etching rate of the first layer can be preferably ensured.

In particular, the present invention is characterized by application of the oxidizing agent in the range of up to but not including, or below the above-described upper limit. It can be said that rather than simply adjusting the oxidation action due to the oxidizing agent, this has been set in relationship to a particular reaction mechanism which is utilized in the present invention or a preferable embodiment thereof. In the processing liquid disclosed in the above-described Patent Literature 5 as a prior art, a large amount of oxidizing agent is adopted. As a result, this is understood that this technique is attributable to the purpose of dissolving a predetermined layer containing Ti exclusively by an oxidizing agent and, at this time, preventing silicon oxide provided in parallel with the predetermined layer from excessive etching by making a hexafluorosilicic acid compound exist together the oxidizing agent. In other words, it can be said that this is to suppress dissolution of silicon in the processing by previously increasing a concentration of silicon (Si) in the system by adding thereto a silicate, thereby decreasing etching performance of the silicon compound layer. In the present invention or a preferable embodiment thereof, the second layer is not a silicon-containing layer, but a metal layer. As a result, the present invention or a preferable embodiment thereof is thought of as being different from the above-described prior art. Specifically, solubility of the second layer such as a contact plug composed of tungsten (W), copper (Cu) and the like depends largely on a concentration of the oxidizing agent, which results in excessive progression of etching in a high concentration region. On the other hand, in a Ti-containing layer as a first layer to be removed, even if the concentration of the oxidizing agent is decreased, an adequate etching performance can be ensured by using together with a hexafluorosilicic acid compound. It is thought that as a result, less of an oxidizing agent can be used and its excellent effects are exerted by coupling with a good protection performance to the second layer and the metal layer, which is achieved by the hexafluorosilicic acid compound.

As the above-described oxidizing agent, one kind thereof may be used solely, or two or more kinds thereof may be used in combination.

(Hexafluorosilicic Acid Compound) Hexafluorosilicic acid is a compound expressed by H₂SiF₆ and examples of its salt include alkali metal salts such as an ammonium salt ((NH₄)₂SiF₆), a potassium salt (K₂SiF₆) and the like. In the present specification, as a general term for hexafluorosilicic acid and its salt, they are called a hexafluorosilicic acid compound.

The hexafluorosilicic acid compound is preferably contained in an amount of 0.05% by mass or more, more preferably in an amount of 0.5% by mass or more, and particularly preferably in an amount of 1% by mass or more, with respect to the total mass amount of the etching liquid of the present embodiment. The upper limit thereof is preferably 30% by mass or less, more preferably 10% by mass or less, still more preferably 5% by mass or less, and particularly preferably 3% by mass or less. Setting to the above-described upper limit or less is preferable from the viewpoint that sufficient etching performance of the first layer can be ensured. Further, setting to the above-described lower limit or greater is preferable because sufficient etching performance of the first layer can be ensured and also etching selectivity of the first layer and the second layer can be increased to a higher level.

In relation to the oxidizing agent, the hexafluorosilicic acid compound is preferably used in an amount of 1 by mass part or more, and more preferably in an amount of 10 by mass parts or more, with respect to 100 by mass parts of the oxidizing agent. The upper limit thereof is preferably 1000 by mass parts or less, more preferably 500 by mass parts or less, and particularly preferably 300 by mass parts or less. By using the amounts of both compounds in a suitable relation, a good etching performance can be realized and also a high etching selectivity can be achieved together as described above.

As the above-described hexafluorosilicic acid compound, one kind thereof may be used solely, or two or more kinds thereof may be used in combination.

### (Anticorrosive Agent)

In the etching liquid of the present invention, it is preferable to contain therein an anticorrosive agent which protects a metal of the second layer from corrosion and damage due to etching. The anticorrosive agent includes a 5- or 6-membered heterocyclic compound (the hetero atom includes nitrogen, oxygen, sulfur and the like) and an aromatic compound. The heterocyclic compound and the aromatic compound may be monocyclic or polycyclic. The heterocyclic compound is preferably a 5-membered heteroaromatic compound. Above all, a 5-membered nitrogen-containing heteroaromatic compound is more preferred. The number of nitrogen to be contained at this time is preferably from 1 to 4. As the aromatic compound, a compound having a benzene ring is preferred.

The anticorrosive agent is preferably a compound represented by any one of the following formulae (I) to (IX).

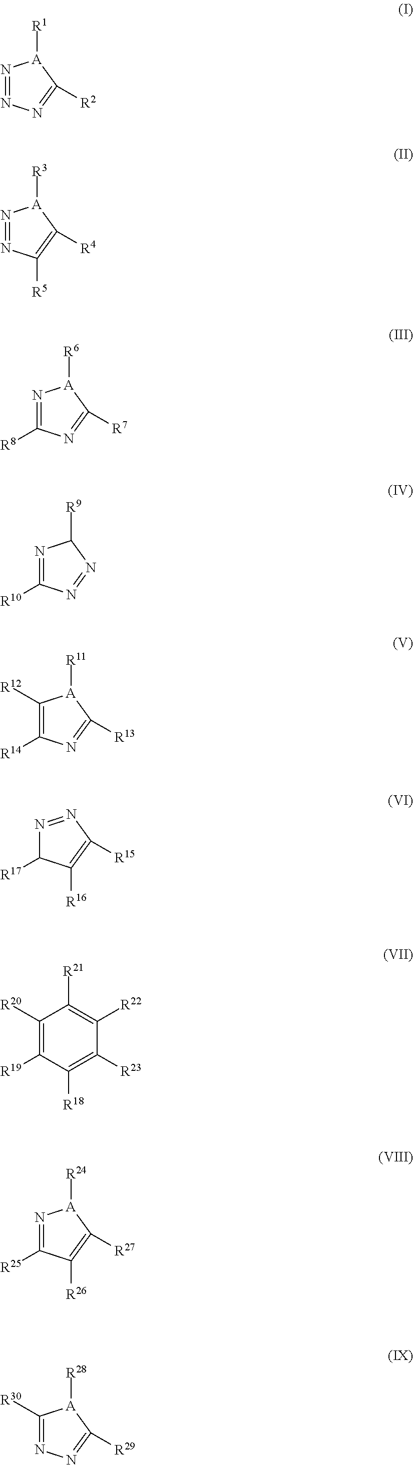

R¹ to R³⁰

In formulae (I) to (IX), R¹ to R³⁰ each independently represent a hydrogen atom or a substituent. Examples of the substituent include an alkyl group (having preferably 1 to 20 carbon atoms, more preferably 1 to 12 carbon atoms, more preferably 1 to 6 carbon atoms, and furthermore preferably 1 to 3 carbon atoms) described below, an alkenyl group (having preferably 2 to 20 carbon atoms, more preferably 2 to 12 carbon atoms, more preferably 2 to 6 carbon atoms, and furthermore preferably 2 to 3 carbon atoms), an aryl group (having preferably 6 to 24 carbon atoms, more preferably 6 to 14 carbon atoms, more preferably 6 to 10 carbon atoms), a heterocyclic group (having preferably 1 to 20 carbon atoms, more preferably 2 to 12 carbon atoms, more preferably 2 to 6 carbon atoms), an alkoxy group (having preferably 1 to 20 carbon atoms, more preferably 1 to 12 carbon atoms, more preferably 1 to 6 carbon atoms, and furthermore preferably 1 to 3 carbon atoms), an acyl group (having preferably 2 to 20 carbon atoms, more preferably 2 to 12 carbon atoms, more preferably 2 to 6 carbon atoms, and furthermore preferably 2 to 3 carbon atoms), an amino group (having preferably 0 to 6 carbon atoms, more preferably 0 to 4 carbon atoms, more preferably 0 to 2 carbon atoms), a carboxyl group, a hydroxy group, a phosphoric acid group, a thiol group (—SH), and a boronic acid group (—B(OH))). Note that, as for the aryl group, a phenyl group or a naphthyl group is preferred. The above-described heterocyclic group includes a nitrogen-containing heteroaromatic group. Above all, a 5-membered nitrogen-containing heteroaromatic group is preferred and a pyrrole group, an imidazole group, a pyrazole group, a triazole group, or a tetrazole group is more preferred. Furthermore, these substituents may have a substituent within the scope in which the effect of the present invention is exerted. Note that, among the above-described substituents, an amino group, a carboxyl group, a phosphoric acid group, and a boronic acid group may form their salts. Examples of the counter ion that forms a salt include quaternary ammonium ions such as ammonium ion (NH₄⁺) and tetramethyl ammonium ion ((CH₃)₄N⁺).

The above-described substituent may be substituted through an arbitrary linking group. The linking group includes an alkylene group (the number of carbon atoms is preferably 1 to 20, more preferably 1 to 12, still more preferably 1 to 6, and still more preferably 1 to 3), an alkenylene group (the number of carbon atoms is preferably 2 to 20, more preferably 2 to 12, still more preferably 2 to 6, and still more preferably 2 to 3), an ether group (—O—), an imino group (the number of carbon atoms is preferably 0 to 4, and more preferably 0 to 2), a thioether group (—S—), a carbonyl group, or a combination thereof. Hereinafter, these linking groups are called “linking group L”. Furthermore, these linking groups may have a substituent within the scope in which the effect of the present invention is exerted.

As R¹ to R³⁰, above all, an alkyl group having 1 to 6 carbon atoms, a carboxyl group, an amino group (the number of carbon atoms is preferably 0 to 4), a hydroxyl group, or a boronic acid group is preferred. As described above, these substituents may be substituted through the linking group L.

Further, as for R¹ to R³⁰, neighbors adjacent to each other may be linked or ring-fused to form a cyclic structure. Examples of the ring structure to be formed include a pyrrole ring structure, an imidazole ring structure, a pyrazole ring structure, or a triazole ring structure. Furthermore, these ring-structural sites may have a substituent within the scope in which the effect of the present invention is exerted. Note that, when the ring structure to be formed is a benzene ring, this ring structure is sectionalized into formula (VII) to organize it.

A

A represents a hetero atom, specifically a nitrogen atom, an oxygen atom, a sulfur atom, or a phosphorous atom. However, when A is divalent (an oxygen atom, or a sulfur atom, there exists none of R¹, R³, R⁶, R¹¹, R²⁴ and R²⁸.

The compound represented by the above-described formula (VII) is preferably a compound represented by any of the following formulae (VII-1) to (VII-4).

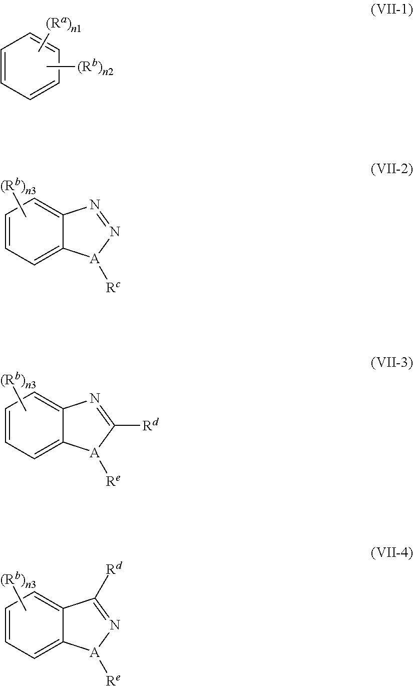

R^{a} represents an acid group, preferably a carboxyl group, a phosphoric acid group, or a boronic acid group. The above-described acid group may be substituted through the above-described linking group L.

R^{b} represents an alkyl group having 1 to 20 carbon atoms (preferably 1 to 12 carbon atoms, more preferably 1 to 6 carbon atoms), an amino group (preferably 0 to 4 carbon atoms), a hydroxyl group, an alkoxy group (preferably 1 to 6 carbon atoms), or an acyl group (preferably 1 to 6 carbon atoms). The above-described substituent R^{b} may be substituted through the above-described linking group L. When R^{b} is an alkyl group, a plurality of R^{b}'s may be linked to form a cyclic alkylene (an unsaturated bond may be incorporated in a part thereof). Alternatively, they may be ring-fused to form a polycyclic aromatic ring.

n1 is an integer of 1 to 5. n2 is an integer of 0 to 5. n3 is an integer of 0 to 4.

In the formulae, A has the same definitions as A defined above. R^{c}, R^{d} and R^{e} are the same groups as the defined groups for R¹ to R³⁰. However, when A is divalent, there exists none of R^{c} and R^{e}.

Hereinafter, examples of the compounds represented by any of the above-described formulae (I) to (IX) are shown. However, the present invention is not construed as being limited on the basis of these compounds.

Note that, in the following exemplified compounds, the case of showing an example of a tautomer thereof is included. The other tautomer is also included in preferable examples of the present invention. The same is also true on the above-described formulae (I) to (IX) and (VII-1) to (VII-4).

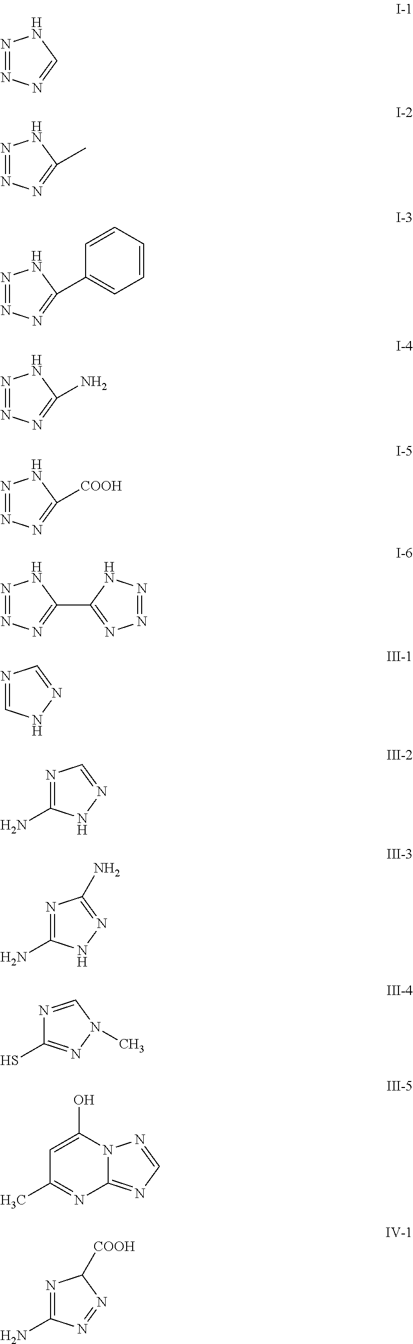

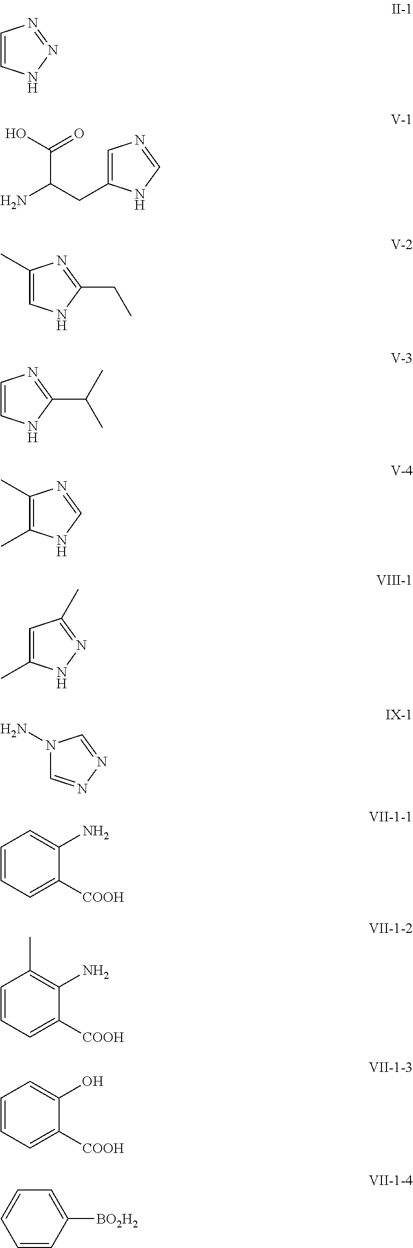

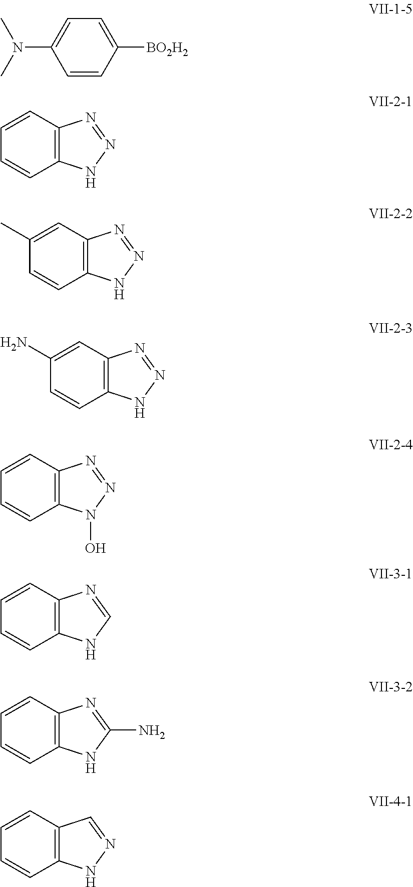

The content of the anticorrosive agent in the etching liquid, although it is not limited in particular, is preferably 0.01% by mass or more, more preferably 0.05% by mass or more, and particularly preferably 0.1% by mass. The upper limit thereof, although it is not limited in particular, is preferably 10% by mass or less, more preferably 5% by mass or less, still more preferably 3% by mass or less, and particularly preferably 1% by mass or less. By setting to the above-described lower limit or greater, a suitable protection effect against the metal layer can be preferably obtained. On the other hand, setting to the above-described upper limit or less is preferable from the viewpoint that the anticorrosive agent does not interfere with good etching performance.

As the above-described anticorrosive agent, one kind thereof may be used solely, or two or more kinds thereof may be used in combination.

### (Aqueous Medium)

The etching liquid of the present invention is preferably an aqueous solution in which water (aqueous medium) is applied as a medium and each of components contained therein is uniformly dissolved. The content of water is preferably from 50 to 99.5% by mass and more preferably from 55 to 95% by mass, with respect to the total mass of the etching liquid. Thus, a composition composed primarily of water (50% by mass or more) is sometimes called as an aqueous composition in particular, and preferable in terms of more inexpensive and more adaptable to the environment, compared to a composition with a high ratio of an organic solvent. It is preferable from this viewpoint that the etching liquid of the present invention is an aqueous composition. The water (aqueous medium) may be an aqueous medium containing components dissolved therein in an amount by which the effects of the present invention are not deteriorated, or may contain inevitable small amount of mixed components. Especially, water which has been subjected to a purifying process, such as distilled water, ion-exchanged water and ultrapure water is preferable and the ultrapure water which is used for production of the semiconductor is particularly preferable.

(pH)

In the present invention, the pH of the etching liquid is preferably controlled to −1 or greater, more preferably 0 or greater. As the upper limit, the pH is preferably controlled to be 5 or less, more preferably 4 or less, and still more preferably 3 or less. Setting to the above-described lower limit or greater is preferable from the viewpoint that not only the etching rate of TiN can be increased to a practical level but also the in-plane uniformity can be improved to a higher level. On the other hand, setting to the above-described upper limit or less is preferable for anticorrosion property to the other substrate such as SiO and SiOC. The pH refers to a value obtained in accordance with equipment and the conditions used for measurement in Examples, unless otherwise indicated.

### (Other Components)

### pH Controlling Agent

In the present embodiment, the pH of the etching liquid is controlled to be within the above-described range and a pH controlling agent is preferably used for the control thereof. As the pH controlling agent, in order to increase the pH, use of quaternary ammonium salts such as tetramethyl ammonium salts, choline and the like, alkali hydroxides such as potassium hydroxide and alkali earth salts, or amino compounds such as 2-aminoethanol, guanidine and the like is preferred. In order to decrease the pH, inorganic acids such as hydrochloric acid, nitric acid, sulfuric acid, and phosphoric acid; and organic acids such as formic acid, acetic acid, propionic acid, butyric acid, valeric acid, 2-methyl butyric acid, n-hexanoic acid, 3,3-dimethyl butyric acid, 2-ethyl butyric acid, 4-methyl pentanoic acid, n-heptanoic acid, 2-methyl hexanoic acid, n-octanoic acid, 2-ethyl hexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid.

The use amount of the pH controlling agent is not particularly limited and an amount necessary to control the pH to the above-described range may be used.

As the above-described pH controlling agent, one kind thereof may be used solely, or two or more kinds thereof may be used in combination.

In the etching liquid used in the present invention, a water-soluble organic solvent may further be added thereto. The water-soluble organic solvent is preferably an organic solvent that can be mixed with water in an arbitrary proportion. Adding the water-soluble organic solvent is effective in terms of enabling to improve in-plane uniform etching property of the wafer.

Examples of the water-soluble organic solvent include: alcohol compound solvents, such as methyl alcohol, ethyl alcohol, 1-propyl alcohol, 2-propyl alcohol, 2-butanol, ethylene glycol, propylene glycol, glycerol, 1,6-hexanediol, cyclohexanediol, sorbitol, xylitol, 2-methyl-2,4-pentanediol, 1,3-butanediol, and 1,4-butanediol; ether compound solvents, such as an alkylene glycol alkyl ether including ethylene glycol monomethyl ether, ethylene glycol monobuthyl ether, diethylene glycol, dipropylene glycol, propylene glycol monomethyl ether, diethylene glycol monomethyl ether, triethylene glycol, poly(ethylene glycol), propylene glycol monomethyl ether, dipropylene glycol monomethyl ether, tripropylene glycol monomethyl ether, diethylene glycol monobutyl ether, and diethylene glycol monobutyl ether.

Among these solvents, preferred are alcohol compound solvents having 2 to 15 carbon atoms and hydroxyl group-containing ether compound solvents having 2 to 15 carbon atoms. More preferred are alcohol compound solvents having 2 to 10 carbon atoms and hydroxyl groups and hydroxyl group-containing ether compound solvents having 2 to 10 carbon atoms. Especially preferred are alkyleneglycol alkylethers having 3 to 8 carbon atoms. The water-soluble organic solvent may be used singly or in combination of two or more kinds appropriately. In the present specification, a compound having a hydroxyl group (—OH) and an ether group (—O—) in the molecule thereof shall be included in the category of the ether compound in principle (not called as the alcohol compound). When a compound having both a hydroxyl group and an ether group is mentioned distinctively in particular, the compound may be preferably called as “hydroxyl group-containing ether compound”.

Especially among these compounds, propyleneglycol and dipropyleneglycol are preferable. The addition amount thereof is preferably from 0.1 to 70% by mass and more preferably from 10 to 50% by mass, with respect to the total mass of the etching liquid. By setting the addition amount to the above-described lower limit or greater, improvement in uniformity of the above-described etching can be effectively realized.

The above-described water-soluble organic solvent is preferably a compound represented by the following formula (0-1).

R¹¹—(—O—R¹³—)ₙ—O—R¹² (O-1)

R¹¹, R¹²

R¹¹ and R¹² are independently a hydrogen atom or an alkyl group having 1 or more and 5 or less carbon atoms. Among these, they are independently preferably an alkyl group having 1 or more and 5 or less carbon atoms, and more preferably an alkyl group having 1 or more and 3 or less carbon atoms.

R¹³

R¹³ is a straight-chain or branched-chain alkylene chain having 1 or more and 4 or less carbon atoms. When a plurality of R¹³'s are present, they may be different from one another.

n

n is an integer of 1 or more and 6 or less.

As the above-described water-soluble organic solvent, one kind thereof may be used solely, or two or more kinds thereof may be used in combination.

It is noted that in the present specification, the representation of the compound (for example, when the name of a chemical is called by putting the term “compound” at the foot of the chemical name) is used in the sense that not only the compound itself, but also its salt, and its ion are incorporated therein. Further, it is used in the sense that the compound means to include a derivative thereof which is modified in a predetermined part within the range of achieving a desired effect.

In the present specification, a substituent (a linking group is also the same) that is not specified by substitution or non-substitution means that the substituent may have an optional substituent. This is applied to the compound that is not specified by substitution or non-substitution. Preferable examples of the substituent include the substituent T described below.

The substituent T includes the following substituents.

The substituents include an alkyl group (preferably an alkyl group having 1 to 20 carbon atom(s), for example, methyl, ethyl, isopropyl, t-butyl, pentyl, heptyl, 1-ethylpentyl, benzyl, 2-ethoxyethyl, and 1-carboxymethyl), an alkenyl group (preferably an alkenyl group having 2 to 20 carbon atoms, for example, vinyl, allyl, and oleyl), an alkynyl group (preferably an alkynyl group having 2 to 20 carbon atoms, for example, ethynyl, butadiynyl, and phenylethynyl), a cycloalkyl group (preferably a cycloalkyl group having 3 to 20 carbon atoms, for example, cyclopropyl, cyclopentyl, cyclohexyl, and 4-methylcyclohexyl), an aryl group (preferably an aryl group having 6 to 26 carbon atoms, for example, phenyl, 1-naphthyl, 4-methoxyphenyl, 2-chlorophenyl, and 3-methylphenyl), a heterocyclic group (preferably a heterocyclic group having 2 to 20 carbon atoms, more preferably a 5- or 6-membered heterocyclic group having at least one hetero atom selected from nitrogen, oxygen and sulfur atoms, for example, 2-pyridyl, 4-pyridyl, 2-imidazolyl, 2-benzimidazolyl, 2-thiazolyl, and 2-oxazolyl), an alkoxy group (preferably an alkoxy group having 1 to 20 carbon atom(s), for example, methoxy, ethoxy, isopropyloxy, and benzyloxy), an aryloxy group (preferably an aryloxy group having 6 to 26 carbon atoms, for example, phenoxy, 1-naphthyloxy, 3-methylphenoxy, and 4-methoxyphenoxy), an alkoxycarbonyl group (preferably an alkoxycarbonyl group having 2 to 20 carbon atoms, for example, ethoxycarbonyl and 2-ethylhexyloxycarbonyl), an amino group (preferably an amino group, an alkylamino group or an aryl amino group having 0 to 20 carbon atom(s), for example, amino, N,N-dimethylamino, N,N-diethylamino, N-ethylamino, and anilino), a sulfamoyl group (preferably a sulfamoyl group having 0 to 20 carbon atom(s), for example, N,N-dimethylsulfamoyl, and N-phenylsulfamoyl), an acyl group (preferably an acyl group having 1 to 20 carbon atom(s), for example, acetyl, propionyl, butyryl and benzoyl), an acyloxy group (preferably an acyloxy group having 1 to 20 carbon atom(s), for example, acetyloxy and benzoyloxy), a carbamoyl group (preferably a carbamoyl group having 1 to 20 carbon atom(s), for example, N,N-dimethylcarbamoyl and N-phenylcarbamoyl), an acylamino group (preferably an acylamino group having 1 to 20 carbon atom(s), for example, acetylamino and benzoylamino), a sulfonamide group (preferably a sulfonamide group having 0 to 20 carbon atom(s) for example, methanesulfonamide, benzenesulfonamide, N-methylmethanesulfonamide, N-ethylbenzenesulfonamide), an alkylthio group (preferably an alkylthio group having 1 to 20 carbon atom(s), for example, methylthio, ethylthio, isopropylthio, benzylthio), an arylthio group (preferably an arylthio group having 6 to 26 carbon atoms, for example, phenylthio, 1-naphthylthio, 3-methylphenylthio, 4-methoxyphenylthio), an alkyl- or aryl-sulfonyl group (preferably an alkyl- or aryl-sulfonyl group having 1 to 20 carbon atoms, for example, methylsulfonyl, ethylsulfonyl, benzenesulfonyl), a hydroxyl group, a carboxyl group, a sulfo group, a cyano group, a halogen atom (for example, a fluorine atom, a chlorine atom, a bromine atom, and an iodine atom). Among them, an alkyl group, an alkenyl group, an aryl group, a heterocyclic group, an alkoxy group, an aryloxy group, an alkoxycarbonyl group, an amino group, an acylamino group, a hydroxyl group, and a halogen atom are more preferable. An alkyl group, an alkenyl group, a heterocyclic group, an alkoxy group, an alkoxycarbonyl group, an amino group, an acylamino group, and a hydroxyl group are particularly preferable.

Further, each of these groups exemplified as the substituent T may be substituted with the above-described substituent T.

In the present specification, as regards each of technical items such as temperature and thickness including choices of substituents and linking groups of the compound, even if lists of the technical items are each independently described, these can be combined mutually.

### (Kit)

The etching liquid of the present invention may be constituted as a kit in which the raw materials thereof are divided into multiple parts. Examples of the kit include an embodiment in which, as a first liquid, a liquid composition in which the above-described hexafluorosilicic acid compound is contained in an aqueous medium is prepared, and, as a second liquid, a liquid composition in which the above-described oxidizing agent is contained in an aqueous medium is prepared. As an example of the use thereof, preferred is an embodiment in which both liquids are mixed to prepare an etching liquid, and after that, the etching liquid is applied to the above-described etching process on a timely basis. This avoids the etching liquid from causing deterioration of the liquid properties due to decomposition of the oxidizing agent (for example, hydrogen peroxide) whereby a desired etching function can be effectively exhibited. Herein, the term “on a timely basis (timely)” after mixing defines the meaning of a period of time prior to a desired function being lost after mixing. Specifically, the period of time is preferably within 60 minutes, more preferably within 30 minutes, and particularly preferably within 10 minutes. Although there is no lower limit in particular, the period of one second or longer is practical. The above-described anticorrosive agent may be contained in the first liquid, or in the second liquid, or in the third liquid described below.

The concentration of the hexafluorosilicic acid compound in the first liquid, although it is not particularly limited, is preferably 0.5% by mass or more and more preferably 1.5% by mass or more. The upper limit thereof is preferably 40% by mass or less and more preferably 30% by mass or less. By setting the concentration to the above-described range, a condition suitable for mixing with the second liquid can be achieved and a favorable concentration region in the above-described etching liquid can be preferably achieved.

The concentration of the oxidizing agent in the second liquid, although it is not particularly limited, is preferably 0.1% by mass or more and more preferably 0.5% by mass or more. The upper limit thereof is preferably 20% by mass or less and more preferably 10% by mass or less. By setting the concentration to the above-described range, a condition suitable for mixing with the first liquid can be achieved and a favorable concentration region in the above-described etching liquid can be preferably achieved.

In the case where the above-described water-soluble organic solvent is used, it is preferable that the water-soluble organic solvent is preliminarily added to the first liquid side. Alternatively, a liquid composition in which a water-soluble organic solvent has been added to an aqueous medium is preliminarily prepared and the liquid composition may be mixed as a third liquid with the first liquid and the second liquid.

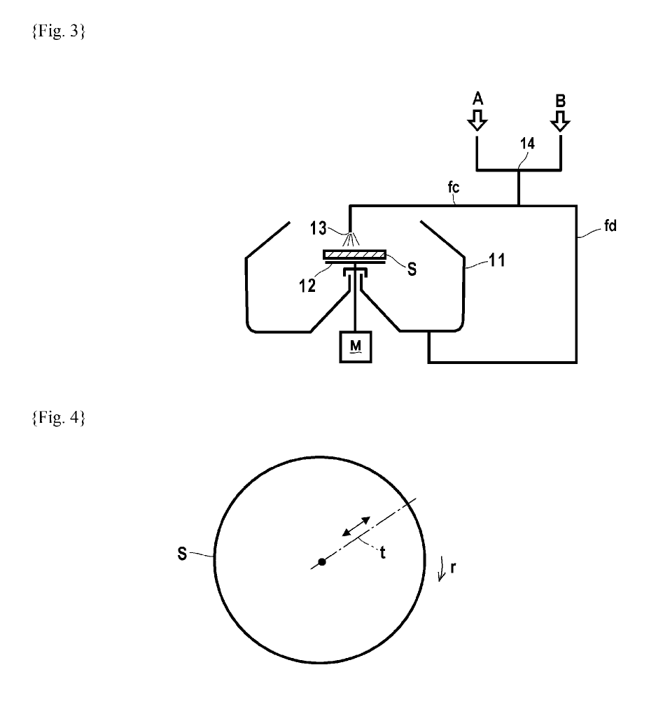

The procedure for mixing the first liquid with the second liquid, although it is not limited, is preferably a method of putting the first liquid and the second liquid into circulation in a separate flow channel and making them converge at the junction portion of the flow channels, thereby mixing them. After that, it is preferable that the etching liquid obtained by convergence is further put into circulation in a flow channel and then discharged or sprayed from a discharge opening, thereby bringing it contact with a semiconductor substrate. In this embodiment, a step of from converging-mixing at the junction portion to contacting with the semiconductor substrate is preferably conducted “on a timely basis (timely)” described above. This is explained below by using FIG. 3. The prepared etching liquid is sprayed from discharge opening 13 and applied onto the upper surface of semiconductor substrate S in reaction container 11. In the embodiment shown in the figure, two liquids of A and B are supplied and converged at junction portion 14. After that, the mixture is moved to discharge opening 13 through flow channel fc. Flow channel fd shows a return path for reuse of the chemical liquid. It is preferable that semiconductor substrate S is placed on rotating table 12 and rotated together with rotating table 12 by means of rotary drive member M. Note that the embodiment using substrate-rotation-type equipment can be also similarly applied to a processing using an etching liquid which is not used in a kit form.

For the anticorrosion performance to SiO and SiOC, it is preferable that a complex compound such as ethylenediamine tetraacetic acid (EDTA) is not used in the etching liquid of the present invention. From the above-described viewpoint, it is preferable that the etching liquid of the present invention is composed substantially of the above-described hexafluorosilicic acid compound, oxidizing agent, and aqueous medium as components thereof, or is composed substantially of the above-described hexafluorosilicic acid compound, oxidizing agent, water-soluble organic solvent, and aqueous medium as components thereof. Herein, the term “substantially” means that the etching liquid may contain components such as inevitable impurities within the range of achieving a desired effect.

### (Container)

The etching liquid of the present invention (whether it is a kit or not) can be stored, transported and used by filling it into an arbitrary container, as far as corrosion resistance properties and the like are not concerned. Further, for semiconductor application, it is preferred that the container have high cleanness and less elution of impurities therefrom. Examples of available containers include “CLEAN BOTTLE” series manufactured by AICELLO CORPORATION, and “PURE BOTTLE” manufactured by KODAMA PLASTICS Co., Ltd. However, the present invention is not limited to these.

### [Conditions of Etching]

In the present embodiment, the conditions for etching are not particularly limited. Either single wafer type (spray-type) etching or immersion type (batch type) etching may be applicable. In the spray-type etching, a semiconductor substrate is transported or rotated in the prescribed direction and an etching liquid is sprayed into the space, thereby bringing the etching liquid into contact with the semiconductor substrate. On the other hand, in the batch-type etching, a semiconductor substrate is immersed in a liquid bath constituted of an etching liquid, thereby bringing the etching liquid into contact with the semiconductor substrate in the liquid bath. These etching processes may be appropriately used depending on the structure, the material, and the like of a device.

The environmental temperature at which etching is conducted is preferably 15° C. or higher, and particularly preferably 25° C. or higher, in the measurement method of temperature in Examples below. The upper limit thereof is preferably 80° C. or lower, and more preferably 60° C. or lower. By setting to the above-described lower limit or higher, etching selectivity to the TiN layer and the second layer can be preferably ensured. By setting the temperature to the above-described upper limit or lower, stability with age of the etching rate can be preferably maintained. The feeding rate of the etching liquid, although it is not particularly limited, is preferably set within the range from 0.05 to 2 L/min, more preferably from 0.05 to 2 L/min and still more preferably from 0.05 to 1 L/min. When a low flow rate is adopted, it is preferable to control the feeding rate to the range from 0.1 to 0.5 L/min. By setting to the above-described lower limit or greater, in-plane uniformity of etching can be preferably secured at more excellent level. By setting to the above-described upper limit or lower, stable selectivity at the time of continuous processing can be preferably secured. In the case of rotating a semiconductor substrate, although it varies depending on the size or the like, from the same viewpoint as the above, it is preferable to rotate the semiconductor substrate at the rate of 50 to 1000 rpm, and more preferably from 50 to 700 rpm. In the case of low rotation, it is preferable to rotate the semiconductor substrate at the rate of from 50 to 400 rpm.

In the case of the batch type, it is also preferable to control the liquid bath to the above-described temperature range from the same reason as the above. The immersing time of the semiconductor substrate, although it is not particularly limited, is preferably set to be from 0.5 to 30 minutes and more preferably from 1 to 10 minutes. By setting to the above-described lower limit or longer, stable selectivity at the time of continuous processing can be preferably secured. By setting to the above-described upper limit or lower, the performance required for reuse of the etching liquid can be preferably maintained.

In the single wafer type etching according to a preferable embodiment of the present invention, it is preferable to transport a semiconductor substrate in the prescribed direction or rotate it and to spray an etching liquid into the space, thereby bringing the etching liquid into contact with the semiconductor substrate. The feeding rate of the etching liquid and the rotation rate of the semiconductor substrate are the same as already described earlier.

In the single wafer type etching equipment configuration according to a preferable embodiment of the present invention, it is preferable to provide an etching liquid while moving a discharge opening (nozzle), as shown in FIG. 4. Specifically, in the present embodiment, when an etching liquid is applied onto semiconductor substrate S having a Ti-containing layer, the substrate is made to rotate in the r direction. On the other hand, the discharge opening is designed to move along with moving-track-line t extending from the central portion of the semiconductor substrate to the edge thereof. Thus, in the present embodiment, the rotation direction of the substrate and the moving direction of the discharge opening are set so as to be a different direction from one another whereby they are subjected to a relative movement with respect to one another. As a result, the configuration is such that an etching liquid can be evenly applied onto the entire surface of the semiconductor substrate whereby the uniformity of etching is favorably secured.

The moving rate of the discharge opening (nozzle), although it is not particularly limited, is preferably 0.1 cm/s or more, more preferably 1 cm/s or more. On the other hand, the upper limit is preferably 30 cm/s or less, more preferably 15 cm/s or less. The moving-track-line may be a straight line or a curve (for example, arc-like). In each case, the moving rate can be calculated from an actual length of the track-line and the time it takes for movement.

### [Residue]

The production process of the semiconductor device may include a step of etching a metal layer or the like on a semiconductor substrate by a plasma etching technique using a resist pattern or the like as a mask. Specifically, etching of the metal layer, a semiconductor layer, an insulating layer, and the like is conducted, thereby patterning the metal layer and the semiconductor layer, or forming, on the insulating layer, an opening portion such as a via hole and a wiring groove. In the plasma etching, a residue derived from the resist used as a mask, and the metal layer, the semiconductor layer, and the insulating layer to be etched may be produced on the semiconductor substrate. In the present invention, the residue produced by the plasma etching as described above is called as “a plasma etching residue”. The “plasma etching residue” includes an etching residue derived from the above-described second layer (Cu, W) and third layer (SiON, SiOC, and the like).

Further, the resist pattern used as a mask is removed after etching. In order to remove the resist pattern, a wet method using a stripper liquid, or a dry method in which ashing is conducted using, for example, plasma or ozone, is used. In the ashing, a converted residue of the plasma etching residue produced by the plasma etching and a residue derived from the resist to be removed are produced on the semiconductor substrate. In the present invention, the residue produced by the ashing as described above is called as an “ashing residue”. Further, as the general term for the residual matter which is produced on the semiconductor substrate and should be removed by washing, such as the plasma etching residue and the ashing residue, they may be simply called as a “residue”.

The plasma etching residue and the ashing residue which are the residue after such etching (Post Etch Residue) are preferably washed and removed using a washing composition. The etching liquid according to the present embodiment can also be applied as a washing liquid for removing the plasma etching residue and/or the ashing residue. Especially, the etching liquid is preferably used to remove both the plasma etching residue and the ashing residue after the plasma ashing which is conducted in succession to the plasma etching.

### [Material to be Processed]

A material, which is etched by applying thereto the etching liquid according to the present embodiment, may be arbitrarily used. However, it is required that a substrate having a first layer containing TiN is applied. Herein, the term “layer containing TiN (TiN layer)” means that the layer may contain oxygen. When the TiN layer is especially used to distinguish it from a layer which does not contain oxygen, it may be called as a TiON layer or the like. In the present invention, the oxygen content of the TiN layer is preferably 10% by mole or less, more preferably 8.5% by mole or less and still more preferably 6.5% by mole or less. When the oxygen concentration is controlled to a lower level, the oxygen level is preferably adjusted to less than 0.1% by mole. It is practical that the lower limit, although it is not particularly limited, is 0.01% by mole or more. Such adjustment of the oxygen concentration in the TiN layer in the substrate can be conducted by, for example, adjustment of the oxygen concentration in a processing room for CVD (Chemical Vapor Deposition) at the time of forming the TiN layer. The above-described oxygen concentration can be specified by the method utilized in Examples described below. Note that the first layer contains TiN as a major ingredient and may contain other ingredients within the range in which the effect of the present invention is exerted. This is true on the other layer such as the second layer, the metal layer and the like.

The above-described first layer is preferably subjected to etching at high etching rate. The thickness of the first layer is not particularly limited. However, when compositions of ordinary devices are considered, it is practical that the thickness is approximately from 0.005 to 0.3 μm. The etching rate (R1) of the first layer is not particularly limited. However, considering production efficiency, the etching rate is preferably from 5 to 1000 Å/min, more preferably from 10 to 500 Å/min, particularly preferably from 50 to 500 Å/min (1 Å=0.1 nm).

In the present embodiment, the etching liquid is preferably applied to a semiconductor substrate having a second layer containing a metal such as Cu, W, Co, Ni, Ag, Ta, Hf, Pt, Au or the like. Further, the method of the present invention is also preferably applied to a semiconductor substrate having a third layer containing a metal compound such as SiO, SiN, SiOC, SiON, or the like. Note that in the present specification, when the composition of a metal compound is expressed by a combination of elements thereof, the composition means that compositions having arbitrary percentage of the elements are incorporated in a broad sense. For example, SiO means that it incorporates a thermally-oxidized film of silicon and SiO₂, and includes SiOₓ. It is preferable for the second layer and the third layer to be kept at a low etching rate. The thickness of the second layer and the third layer is not particularly limited. However, when compositions of ordinary devices are considered, it is practical that the thickness is approximately from 0.005 to 0.5 μm. The etching rates [R2] and [R3] of the second layer and the third layer are not particularly limited. However, when production efficiency is considered, the etching rate is preferably from 0.001 to 100 Å/min, more preferably from 0.01 to 50 Å/min.

The exposed width (d in the figure) of the metal layer is not limited in particular. However, from the viewpoint that advantages of the present invention become more remarkable, the exposed width is preferably 5 nm or more, and more preferably 10 nm or more. The upper limit is preferably 1000 nm or less, and more preferably 100 nm or less.

In the selective etching of the first layer, its etching rate ratio ([R1]/[R2]) is not particularly limited. However, when described based on the premise of a device that needs a high selectivity, the etching rate ratio is preferably 2 or more, more preferably 3 or more, still more preferably 5 or more. The upper limit is not particularly limited and a higher upper limit produces more preferable effects. However, it is practical that the upper limit is 1000 or less. Note that this preferable range is the same as in [R1]/[R3].

### [Production of Semiconductor Substrate Product]

In the present embodiment, a semiconductor substrate product having a desired structure is preferably produced through a step of providing a semiconductor substrate by forming the above-described first layer, second layer and/or third layer on a silicon wafer and a step of applying the etching liquid onto the semiconductor substrate thereby selectively dissolving the first layer. At this moment, the above-described specific etching liquid is used for etching. It is preferable that the semiconductor substrate (second layer and/or third layer) is subjected, prior to the above-described etching step, to a dry etching or dry asking step. Further, it is preferable that a residue produced in the step is removed.

Note that, in the present specification, as regards each of the steps involved in the etching and the method of producing the semiconductor substrate, it is allowed to rearrange the order of the steps arbitrarily and to apply them within the range in which the effect of the present invention is exerted. Further, the expression “preparation” means to prepare a particular material by synthesis or blend and in addition, to include procurement of prescribed materials by purchase or the like. Further, in the present specification, to utilize an etching liquid so as to etch each material of the semiconductor substrate is called “application”. The embodiment thereof is not limited in particular. For example, this term is broad enough to include any embodiment of bringing an etching liquid and a semiconductor substrate into contact. Specifically, etching may be carried out by immersion using batch-type equipment, or may be carried out by discharge using single wafer-type equipment.

### EXAMPLES

The present invention will be described in more detail based on examples given below, but the invention is not meant to be limited by these. Note that the concentration or composition shown in the Examples is based on mass standard, unless otherwise indicated.

### Example 1 and Comparative Example 1

Etching liquids were prepared to contain components shown in the following Table 1 in accordance with the compositions (% by mass) shown in the same table. Note that the balance is water (ultra-pure water). All of “%” in the table indicate % by mass.

### (Method of Forming a TiN Substrate)

A TiN film having a surface oxygen concentration of less than 0.1% by mole was formed on a commercially available silicon substrate by CVD (Chemical Vapor Deposition). Further, film formation for a second layer substrate was carried out by CVD in the same manner as the above to use it as a test substrate in tables.

### (Substrate Oxygen Concentration)

Regarding a surface oxygen concentration of the TiN layer, concentration profiles of Ti, 0 and N in the depth direction from 0 to 30 nm were measured using etching ESCA (Quantera manufactured by ULVAC-PHI, INCORPORATED) and each of the contents at the depth of from 5 to 10 nm was calculated. An average of the oxygen contents was defined as the surface oxygen concentration.

### (Etching Test)

With respect to the above-described test substrates, etching was carried out under the following conditions using single wafer-type equipment (POLOS (trade name) manufactured by SPS-Europe B.V.) and evaluation tests were carried out. Note that the time required from preparation of the liquids to an etching liquid processing was adjusted within 5 minutes.

processing temperature: 25° C.

Discharge rate: 1 L/min.

Wafer rotation number: 500 rpm

### (Measurement Method of Processing Temperature)

A radiation thermometer IT-550F (trade name) manufactured by HORIBA, Ltd. was fixed at the height of 30 cm above the wafer in single wafer type equipment. The thermometer was pointed onto the wafer surface of 2 cm outside of the wafer center, and temperature measurement was conducted while making a chemical liquid flow. The temperature was measured by digital output from the radiation thermometer and continuously recorded on a personal computer. Among them, an averaged value of the temperature during the period of 10 seconds after stabilization of the temperature was used as a temperature on the wafer.

### (Etching Rate)

The etching rate (Rx) was calculated by measurement of the film thickness before and after the etching processing using ellipsometry (Spectroscopic ellipsometer VASE, manufactured by J. A. Woollam Japan was used). A mean value of 5 points was adopted (measurement condition and measurement range: 1.2-2.5 eV, measured angle: 70 and 75 degrees).

### (Measurement of pH)

The pH in Table is a value obtained by measurement at room temperature (25° C.) using F-51 (trade name) manufactured by HORIBA, Ltd.

TABLE 1

| | HFSi | Oxidizing agent | | TiN [R_{TiN}] | Cu [R_{Cu}] | | W [R_{W}] | |
|---|---|---|---|---|---|---|---|---|
| Test | (content) | (content) | pH | (Å/min) | (Å/min) | TiN/Cu | (Å/min) | TiN/W |
| 101 | H₂SiF₆ (2.0%) | HNO₃ (0.1%) | 2 | 163 | 47 | 3.5 | 21 | 7.8 |
| C11a | | HNO₃ (0.1%) | 2 | 0.6 | 7 | 0.1 | 1 | 0.6 |
| C12a | H₂SiF₆ (2.0%) | | 2 | 0.3 | 2 | 0.2 | 1 | 0.3 |

| | HFSi | Oxidizing agent | | TiN [R_{TiN}] | Co [R_{Co}] | | Ni [R_{Ni}] | | Ag [R_{Ag}] | |
|---|---|---|---|---|---|---|---|---|---|---|
| Test | (content) | (content) | pH | (Å/min) | (Å/min) | TiN/Co | (Å/min) | TiN/Ni | (Å/min) | TiN/Ag |
| 102 | H₂SiF₆ (2.0%) | HNO₃ (0.1%) | 2 | 163 | 6 | 27.2 | 15 | 10.9 | 2 | 81.5 |
| C11b | | HNO₃ (0.1%) | 2 | 0.6 | 3 | 0.2 | 12 | 0.1 | 1 | 0.6 |
| C12b | H₂SiF₆ (2.0%) | | 2 | 0.3 | 1 | 0.3 | 6 | 0.1 | 1 | 0.3 |

| | HFSi | Oxidizing agent | | TiN [R_{TiN}] | Ta [R_{Ta}] | | Hf [R_{Hf}] | | Pt [R_{Pt}] | | Au [R_{Au}] | |
|---|---|---|---|---|---|---|---|---|---|---|---|---|
| Test | (content) | (content) | pH | (Å/min) | (Å/min) | TiN/Ta | (Å/min) | TiN/Hf | (Å/min) | TiN/Pt | (Å/min) | TiN/Au |
| 103 | H₂SiF₆ (2.0%) | HNO₃ (0.1%) | 2 | 163 | 1 | 163.0 | 1 | 163.0 | 1 | 163.0 | 2 | 81.5 |
| C11c | | HNO₃ (0.1%) | 2 | 0.6 | 1 | 0.6 | 1 | 0.6 | 1 | 0.6 | 1 | 0.6 |
| C12c | H₂SiF₆ (2.0%) | | 2 | 0.3 | 1 | 0.3 | 1 | 0.3 | 1 | 0.3 | 1 | 0.3 |

HFSi stands for a hexafluorosilicic acid compound (The same shall apply hereafter).
Tests beginning with C indicate Comparative Examples (The same shall apply hereafter).

From the results shown above, it is found that the etching liquid of the present invention makes it possible to obtain a good etching selectivity whereby TiN is predominantly removed.

### Example 2, Comparative Example 2

Etching tests were carried out in the same manner as Example 1, except that the concentration and the like of the additives to be used were changed as shown in Tables 2 to 6. The results are shown in Tables 2 to 6.

TABLE 2

| | HFSi | Oxidizing agent | Anticorrosive agent | | TiN [R_{TiN}] | Cu [R_{Cu}] | | W [R_{W}] | |
|---|---|---|---|---|---|---|---|---|---|
| Test | (content) | (content) | (content) | pH | (Å/min) | (Å/min) | TiN/Cu | (Å/min) | TiN/W |
| 200 | H₂SiF₆ (0.1%) | HNO₃ (0.1%) | BTA (0.5%) | 2 | 35 | 4 | 8.8 | 9 | 3.9 |
| 201 | H₂SiF₆ (0.5%) | HNO₃ (0.1%) | BTA (0.5%) | 2 | 65 | 6 | 10.8 | 10 | 6.5 |
| 202 | H₂SiF₆ (2.0%) | HNO₃ (0.1%) | BTA (0.5%) | 2 | 158 | 7 | 22.6 | 11 | 14.4 |
| 203 | H₂SiF₆ (5.0%) | HNO₃ (0.1%) | BTA (0.5%) | 2 | 210 | 11 | 19.1 | 17 | 12.4 |
| 204 | H₂SiF₆ (10.0%) | HNO₃ (0.1%) | BTA (0.5%) | 2 | 232 | 15 | 15.5 | 25 | 9.3 |
| C21 | | HNO₃ (0.1%) | BTA (0.5%) | 2 | 0.3 | 3 | 0.1 | 2 | 0.2 |

BTA: Benzotriazole (the same abbreviated notation also in the following tables)

TABLE 3

| | HFSi | Oxidizing agent | Anticorrosive agent | | TiN [R_{TiN}] | Cu [R_{Cu}] | | W [R_{W}] | |
|---|---|---|---|---|---|---|---|---|---|
| Test | (content) | (content) | (content) | pH | (Å/min) | (Å/min) | TiN/Cu | (Å/min) | TiN/W |
| 300 | H₂SiF₆ (2.0%) | HNO₃ (0.1%) | BTA (0.5%) | 2 | 158 | 7 | 22.6 | 11 | 14.4 |
| 301 | H₂SiF₆ (2.0%) | HNO₃ (0.5%) | BTA (0.5%) | 2 | 198 | 25 | 7.9 | 15 | 13.2 |
| 302 | H₂SiF₆ (2.0%) | HNO₃ (1.0%) | BTA (0.5%) | 2 | 226 | 85 | 2.7 | 24 | 9.4 |
| 303 | H₂SiF₆ (2.0%) | HNO₃ (5.0%) | BTA (0.5%) | 2 | 247 | 123 | 2.0 | 36 | 6.9 |
| 304 | H₂SiF₆ (2.0%) | HNO₃ (9.5%) | BTA (0.5%) | 2 | 285 | 186 | 1.5 | 37 | 7.7 |
| 305 | H₂SiF₆ (2.0%) | H₂O₂ (0.5%) | BTA (0.5%) | 2 | 78 | 8 | 9.8 | 19 | 4.1 |
| 306 | H₂SiF₆ (2.0%) | H₂O₂ (1.0%) | BTA (0.5%) | 2 | 103 | 19 | 5.4 | 25 | 4.1 |
| 307 | H₂SiF₆ (2.0%) | H₂O₂ (3.0%) | BTA (0.5%) | 2 | 142 | 36 | 3.9 | 41 | 3.5 |
| 308 | H₂SiF₆ (2.0%) | H₂O₂ (5.0%) | BTA (0.5%) | 2 | 179 | 61 | 2.9 | 68 | 2.6 |
| C31 | H₂SiF₆ (2.0%) | | BTA (0.5%) | 2 | 0.1 | 3 | 0.03 | 2 | 0.1 |
| C32 | H₂SiF₆ (2.0%) | HNO₃ (20%) | BTA (0.5%) | 2 | 362 | 458 | 0.8 | 289 | 1.3 |
| C33 | H₂SiF₆ (2.0%) | H₂O₂ (15%) | BTA (0.5%) | 2 | 291 | 397 | 0.7 | 209 | 1.4 |

TABLE 4

| | HFSi | Oxidizing agent | Anticorrosive agent | | TiN [R_{TiN}] | Cu [R_{Cu}] | | W [R_{W}] | |
|---|---|---|---|---|---|---|---|---|---|
| Test | (content) | (content) | (content) | pH | (Å/min) | (Å/min) | TiN/Cu | (Å/min) | TiN/W |
| 400 | H₂SiF₆ (2.0%) | HNO₃ (0.1%) | BTA (0.5%) | −1 | 242 | 89 | 2.7 | 10 | 24.2 |
| 401 | H₂SiF₆ (2.0%) | HNO₃ (0.1%) | BTA (0.5%) | 0 | 192 | 43 | 4.5 | 10 | 19.2 |
| 402 | H₂SiF₆ (2.0%) | HNO₃ (0.1%) | BTA (0.5%) | 2 | 158 | 7 | 22.6 | 11 | 14.4 |
| 403 | H₂SiF₆ (2.0%) | HNO₃ (0.1%) | BTA (0.5%) | 3.5 | 123 | 6 | 20.5 | 16 | 7.7 |
| 404 | H₂SiF₆ (2.0%) | HNO₃ (0.1%) | BTA (0.5%) | 5 | 86 | 5 | 17.2 | 38 | 2.3 |
| 405 | H₂SiF₆ (2.0%) | HNO₃ (0.1%) | BTA (0.5%) | 9 | 13 | 1 | 13.0 | 256 | 0.1 |

TABLE 5

| | HFSi | Oxidizing agent | Anticorrosive agent | | TiN [R_{TiN}] | Cu [R_{Cu}] | | W [R_{W}] | |
|---|---|---|---|---|---|---|---|---|---|
| Test | (content) | (content) | (content) | pH | (Å/min) | (Å/min) | TiN/Cu | (Å/min) | TiN/W |
| 500 | H₂SiF₆ (2.0%) | HNO₃ (0.1%) | BTA (0.5%) | 2 | 158 | 7 | 22.6 | 11 | 14.4 |
| 501 | (NH₄)₂SiF₆ (2.0%) | HNO₃ (0.1%) | BTA (0.5%) | 2 | 143 | 9 | 15.9 | 12 | 11.9 |
| 502 | K₂SiF₆ (2.0%) | HNO₃ (0.1%) | BTA (0.5%) | 2 | 123 | 8 | 15.4 | 11 | 11.2 |

TABLE 6

| | HFSi | Oxidizing agent | Anticorrosive agent | | TiN [R_{TiN}] | SiO [R_{SiO}] | | SiN [R_{SiN}] | |
|---|---|---|---|---|---|---|---|---|---|
| Test | (content) | (content) | (content) | pH | (Å/min) | (Å/min) | TiN/SiO | (Å/min) | TiN/SiN |
| 601 | H₂SiF₆ (2.0%) | HNO₃ (0.1%) | BTA (0.5%) | 2 | 158 | 1 | 158.0 | 0.5 | 316.0 |
| | HFSi | Oxidizing agent | Anticorrosive agent | | TiN [R_{TiN}] | SiOC[R_{SIOC}] | | SiON[R_{SION}] | |
| Test | (content) | (content) | (content) | pH | (Å/min) | (Å/min) | TiN/SiOC | (Å/min) | TiN/SiON |
| 602 | H₂SiF₆ (2.0%) | HNO₃ (0.1%) | BTA (0.5%) | 2 | 158 | 6 | 26.3 | 3 | 52.7 |

As is apparent from the results shown above, it is found that a suitable performance is obtained, according to the present invention, in a broad concentration range of each ingredient and pH region. Further, it is found that much higher selectivity can be exerted by an appropriate adjustment of the concentration and the pH as required. Further, it is found that a desired effectiveness is exhibited even if the form of salts of hexafluorosilicic acid is changed.

### Example 3

Etching tests were carried out in the same manner as Example 1, except that anticorrosive agents shown in the following Table 7 were used. The results are shown in Table 7.

TABLE 7

| | HFSi | Oxidizing agent | Anticorrosive agent | | TiN [R_{TiN}] | Cu [R_{Cu}] | | W [R_{W}] | |
|---|---|---|---|---|---|---|---|---|---|
| Test | (content) | (content) | (content) | pH | (Å/min) | (Å/min) | TiN/Cu | (Å/min) | TiN/W |
| 700 | H₂SiF₆ (2.0%) | HNO₃ (0.1%) | | 2 | 163 | 47 | 3.5 | 21 | 7.8 |
| 701 | H₂SiF₆ (2.0%) | HNO₃ (0.1%) | VII-2-1 (0.5%) | 2 | 158 | 7 | 22.6 | 11 | 14.4 |
| 702 | H₂SiF₆ (2.0%) | HNO₃ (0.1%) | I-1 (0.5%) | 2 | 147 | 11 | 13.4 | 13 | 11.3 |
| 703 | H₂SiF₆ (2.0%) | HNO₃ (0.1%) | I-2 (0.5%) | 2 | 143 | 10 | 14.3 | 14 | 10.2 |
| 704 | H₂SiF₆ (2.0%) | HNO₃ (0.1%) | I-3 (0.5%) | 2 | 152 | 6 | 25.3 | 9 | 16.9 |
| 705 | H₂SiF₆ (2.0%) | HNO₃ (0.1%) | I-4 (0.5%) | 2 | 151 | 5 | 30.2 | 10 | 15.1 |
| 706 | H₂SiF₆ (2.0%) | HNO₃ (0.1%) | I-5 (0.5%) | 2 | 132 | 12 | 11.0 | 14 | 9.4 |
| 707 | H₂SiF₆ (2.0%) | HNO₃ (0.1%) | I-6 (0.5%) | 2 | 157 | 8 | 19.6 | 12 | 13.1 |
| 708 | H₂SiF₆ (2.0%) | HNO₃ (0.1%) | VII-2-2 (0.5%) | 2 | 163 | 9 | 18.1 | 10 | 16.3 |
| 709 | H₂SiF₆ (2.0%) | HNO₃ (0.1%) | VII-2-3 (0.5%) | 2 | 146 | 12 | 12.2 | 15 | 9.7 |
| 710 | H₂SiF₆ (2.0%) | HNO₃ (0.1%) | VII-2-4 (0.5%) | 2 | 148 | 21 | 7.0 | 16 | 9.3 |
| 711 | H₂SiF₆ (2.0%) | HNO₃ (0.1%) | III-1 (0.5%) | 2 | 149 | 28 | 5.3 | 20 | 7.5 |
| 712 | H₂SiF₆ (2.0%) | HNO₃ (0.1%) | III-2 (0.5%) | 2 | 159 | 6 | 26.5 | 8 | 19.9 |
| 713 | H₂SiF₆ (2.0%) | HNO₃ (0.1%) | III-3 (0.5%) | 2 | 161 | 9 | 17.9 | 10 | 16.1 |
| 714 | H₂SiF₆ (2.0%) | HNO₃ (0.1%) | IX-1 (0.5%) | 2 | 156 | 9 | 17.3 | 8 | 19.5 |
| 715 | H₂SiF₆ (2.0%) | HNO₃ (0.1%) | III-4 (0.5%) | 2 | 146 | 19 | 7.7 | 18 | 8.1 |
| 716 | H₂SiF₆ (2.0%) | HNO₃ (0.1%) | VI-1 (0.5%) | 2 | 149 | 23 | 6.5 | 19 | 7.8 |
| 717 | H₂SiF₆ (2.0%) | HNO₃ (0.1%) | III-5 (0.5%) | 2 | 143 | 18 | 7.9 | 15 | 9.5 |
| 718 | H₂SiF₆ (2.0%) | HNO₃ (0.1%) | VII-3-1 (0.5%) | 2 | 146 | 17 | 8.6 | 13 | 11.2 |
| 719 | H₂SiF₆ (2.0%) | HNO₃ (0.1%) | VII-3-2 (0.5%) | 2 | 147 | 11 | 13.4 | 11 | 13.4 |
| 720 | H₂SiF₆ (2.0%) | HNO₃ (0.1%) | V-1 (0.5%) | 2 | 149 | 13 | 11.5 | 9 | 16.6 |
| 721 | H₂SiF₆ (2.0%) | HNO₃ (0.1%) | V-3 (0.5%) | 2 | 148 | 14 | 10.6 | 8 | 18.5 |
| 722 | H₂SiF₆ (2.0%) | HNO₃ (0.1%) | V-4 (0.5%) | 2 | 151 | 12 | 12.6 | 10 | 15.1 |
| 723 | H₂SiF₆ (2.0%) | HNO₃ (0.1%) | VIII-1 (0.5%) | 2 | 146 | 25 | 5.8 | 17 | 8.6 |
| 724 | H₂SiF₆ (2.0%) | HNO₃ (0.1%) | VII-4-1 (0.5%) | 2 | 151 | 15 | 10.1 | 13 | 11.6 |
| 725 | H₂SiF₆ (2.0%) | HNO₃ (0.1%) | VII-1-1 (0.5%) | 2 | 153 | 14 | 10.9 | 12 | 12.8 |
| 726 | H₂SiF₆ (2.0%) | HNO₃ (0.1%) | VII-1-2 (0.5%) | 2 | 154 | 13 | 11.8 | 14 | 11.0 |
| 727 | H₂SiF₆ (2.0%) | HNO₃ (0.1%) | VII-1-3 (0.5%) | 2 | 153 | 12 | 12.8 | 13 | 11.8 |
| 728 | H₂SiF₆ (2.0%) | HNO₃ (0.1%) | VII-1-4 (0.5%) | 2 | 159 | 10 | 15.9 | 10 | 15.9 |
| 729 | H₂SiF₆ (2.0%) | HNO₃ (0.1%) | VII-1-5 (0.5%) | 2 | 154 | 14 | 11.0 | 11 | 14.0 |
| 730 | H₂SiF₆ (2.0%) | HNO₃ (0.1%) | II-1 (0.5%) | 2 | 148 | 16 | 9.3 | 17 | 8.7 |

As is apparent from the results shown above, it is found that application of the anticorrosive agent on demand makes it possible to exert a higher selectivity, according to the present invention.

### Example 4

Etching tests were carried out in the same manner as Example 1, except that the etching conditions shown in the following Table 8 were applied. The results are shown in Table 8.

TABLE 8

| | | | | | Processing | | | |
|---|---|---|---|---|---|---|---|---|
| | HFSi | Oxidizing agent | Anticorrosive agent | | temperature | | Swing speed | |
| Test | (content) | (content) | (content) | pH | (° C.) | Water washing | (cm/s) | Etching equipment |
| 800 | H₂SiF₆ (0.1%) | HNO₃ (0.1%) | BTA (0.5%) | 2 | 25 | carried out | 7 | single wafer type |
| 801 | H₂SiF₆ (0.1%) | HNO₃ (0.1%) | BTA (0.5%) | 2 | 35 | carried out | 7 | single wafer type |
| 802 | H₂SiF₆ (0.1%) | HNO₃ (0.1%) | BTA (0.5%) | 2 | 45 | carried out | 7 | single wafer type |
| 803 | H₂SiF₆ (0.1%) | HNO₃ (0.1%) | BTA (0.5%) | 2 | 60 | carried out | 7 | single wafer type |
| 804 | H₂SiF₆ (0.1%) | HNO₃ (0.1%) | BTA (0.5%) | 2 | 70 | carried out | 7 | single wafer type |
| 805 | H₂SiF₆ (0.1%) | HNO₃ (0.1%) | BTA (0.5%) | 2 | 80 | carried out | 7 | single wafer type |
| 806 | H₂SiF₆ (0.1%) | HNO₃ (0.1%) | BTA (0.5%) | 2 | 25 | not carried out | 7 | single wafer type |
| 807 | H₂SiF₆ (0.1%) | HNO₃ (0.1%) | BTA (0.5%) | 2 | 25 | carried out | 1 | single wafer type |
| 808 | H₂SiF₆ (0.1%) | HNO₃ (0.1%) | BTA (0.5%) | 2 | 25 | carried out | 3 | single wafer type |
| 809 | H₂SiF₆ (0.1%) | HNO₃ (0.1%) | BTA (0.5%) | 2 | 25 | carried out | 5 | single wafer type |
| 810 | H₂SiF₆ (0.1%) | HNO₃ (0.1%) | BTA (0.5%) | 2 | 25 | carried out | 15 | single wafer type |
| 811 | H₂SiF₆ (0.1%) | HNO₃ (0.1%) | BTA (0.5%) | 2 | 25 | carried out | 0 | single wafer type |
| 812 | H₂SiF₆ (0.1%) | HNO₃ (0.1%) | BTA (0.5%) | 2 | 25 | carried out | — | batch type |

| | | | | |
|---|---|---|---|---|
| | | | Defect in | In-plane |
| TiN [R_{TiN}] | Cu [R_{Cu}] | W [R_{W}] | perfor- | uniformity |

| Test | (Å/min) | (Å/min) | TiN/Cu | (Å/min) | TiN/W | mance | (%) |
|---|---|---|---|---|---|---|---|
| 800 | 158 | 7 | 22.6 | 11 | 14.4 | A | A |
| 801 | 168 | 10 | 17 | 14 | 12 | A | A |
| 802 | 180 | 15 | 12 | 15 | 12 | A | A |
| 803 | 256 | 26 | 10 | 18 | 14 | A | A |
| 804 | 287 | 32 | 9 | 20 | 14 | A | A |
| 805 | 321 | 48 | 7 | 28 | 11 | B | A |
| 806 | 158 | 7 | 23 | 11 | 14 | C | A |
| 807 | 148 | 9 | 16 | 13 | 11 | A | B |
| 808 | 153 | 8 | 19 | 13 | 12 | A | A |
| 809 | 157 | 7 | 22 | 12 | 13 | A | A |
| 810 | 154 | 7 | 22 | 11 | 14 | A | B |
| 811 | 143 | 9 | 16 | 14 | 10 | A | C |
| 812 | 141 | 11 | 13 | 16 | 9 | B | C |

As is apparent from the above results, it is found that a preferable performance is exhibited, according to the present invention, by any of the single wafer-type equipment and the batch-type equipment. Further, it is found that the single wafer-type equipment in particular allows exertion of higher selectivity and in-plane uniformity.

Note that the defect in performance and the in-plane uniformity shown in the above Table were each evaluated as follows.

### [Evaluation of Defect in Performance]

The wafer surface after etching was observed using a Defect Inspection System (trade name SP-1, manufactured by KLA-Tencor Corporation) and evaluation was conducted with respect to the number of TiN residue on the surface. Measurement was conducted on the condition that when a residue having a size of 0.2 μm or greater was present, the defect number was 1.

The defect number in terms of 0.2 μm or greater was:

A: less than 50/12 inch wafer surface

B: 50 or more and less than 200/12 inch wafer surface

C: 200 or more/12 inch wafer surface

[Evaluation of in-Plane Uniformity of 12 Inch Wafer]

Condition setting required for the etching depth at the center of a circular substrate (12 inches in diameter) was conducted at different time periods whereby the time period required to be 300 angstrom of the etching depth was confirmed. Then, the entire substrate was again etched at the confirmed time period, and at this moment, the measurement of the obtained etching depth was conducted at the centrally-directed position of 30 mm from the periphery of the substrate. Evaluation was conducted on the condition that as the depth is near 300 angstrom, in-plane uniformity becomes high. Specific criteria are as follows. In this measurement, 10-point measuring positions were set and thus evaluation was performed in terms of average value thereof.

A ±10 or more and less than 50 angstrom

B ±50 or more and less than 100 angstrom

C ±100 or more and less than 150 angstrom

Further, TiN substrates were produced by changing the surface oxygen concentration of TiN in Test 803 to 0.2, 1.9, 4.1, 6.0, 8.1, 9.9, and 12.1% by mole respectively and the same test as the above was carried out. As a result, it was found that defect in performance of the TiN substrate was improved to a higher level.

Having described our invention as related to the present embodiments, it is our intention that the invention not be limited by any of the details of the description, unless otherwise specified, but rather be construed broadly within its spirit and scope as set out in the accompanying claims.

### REFERENCE SIGNS LIST

1 TiN layer (first layer)
2 SiON layer (third layer (1))
3 SiOC layer (third layer (2))
4 Cu/W layer (second layer)
5 via
10, 20 semiconductor substrate
11 reaction container
12 rotating table
13 discharge opening
14 junction portion
S substrate

1. An etching liquid for processing a substrate having a first layer containing titanium nitride (TiN) and a second layer containing at least one metal selected from transition metals belonging to group 3 to group 11 of the periodic table thereby removing the first layer selectively, wherein the etching liquid contains a hexafluorosilicic acid compound, and an oxidizing agent of which concentration is 0.05% by mass or more and less than 10% by mass.

2. The etching liquid according to claim 1, wherein the second layer contains at least one metal selected from Co, Ni, Cu, Ag, Ta, Hf, W, Pt and Au.

3. The etching liquid according to claim 1, wherein the hexafluorosilicic acid compound is selected from hexafluorosilicic acid, ammonium hexafluorosilicate, and potassium hexafluorosilicate.

4. The etching liquid according to claim 1, wherein the oxidizing agent is nitric acid or hydrogen peroxide.

5. The etching liquid according to claim 1, wherein a rate ratio (R1/R2) of an etching rate (R1) of the first layer and an etching rate (R2) of the second layer is 2 or more.

6. The etching liquid according to claim 1, further containing an anticorrosive agent for the second layer.

7. The etching liquid according to claim 6, wherein the anticorrosive agent is composed of a compound represented by any one of the following formulae (I) to (IX): 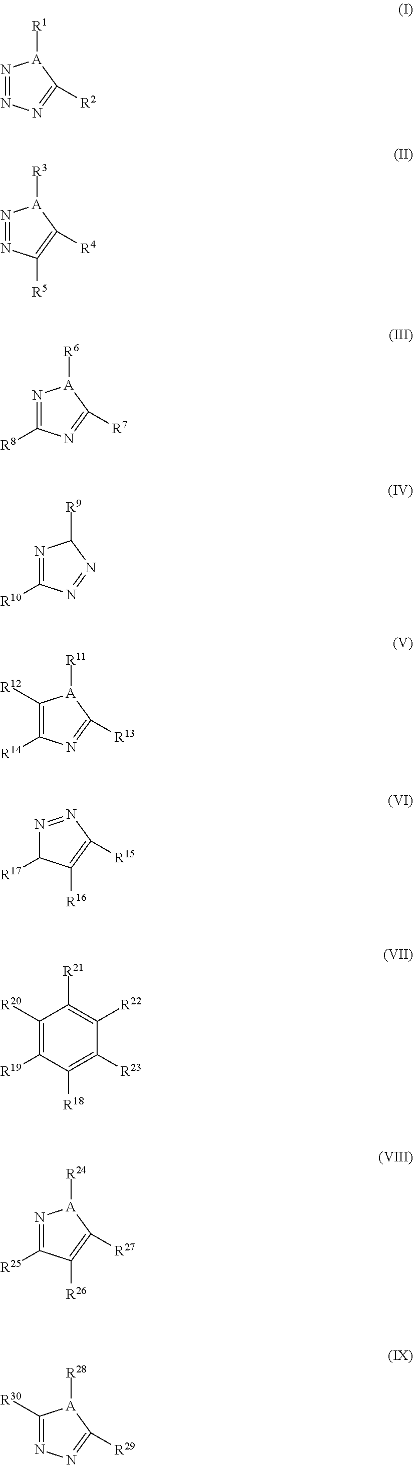
wherein R¹ to R³⁰ each independently represent a hydrogen atom or a substrate; in this case, neighbors adjacent to each other may be ring-fused to form a cyclic structure; A represents a hetero atom with the proviso that when A is divalent, there exists none of R¹, R³, R⁶, R¹¹, R²⁴ and R²⁸ by which A is each substituted.

8. The etching liquid according to claim 6, wherein the anticorrosive agent is contained in a range of from 0.01 to 10% by mass.

9. The etching liquid according to claim 1, wherein a pH is from −1 to 5.

10. An etching method comprising, at the time of processing a substrate having a first layer containing titanium nitride (TiN) and a second layer containing at least one metal selected from transition metals belonging to group 3 to group 11 of the periodic table, processing by applying an etching liquid containing a hexafluorosilicic acid compound, and an oxidizing agent of which concentration is 0.05% by mass or more and less than 10% by mass, to the substrate.

11. The etching method according to claim 10, wherein the second layer has at least one metal selected from Co, Ni, Cu, Ag, Ta, Hf, W, Pt and Au.

12. The etching method according to claim 10, wherein the substrate further has a third layer containing at least one metal compound selected from the group consisting of SiO, SiN, SiOC and SiON.

13. The etching method according to claim 12, wherein the first layer containing titanium nitride (TiN) is layered on the upper part than the third layer in order to protect the third layer.

14. The etching method according to claim 10, wherein the method of applying the etching liquid to the substrate contains a step of supplying the etching liquid onto the substrate from above the substrate while rotating the substrate.

15. The etching method according to claim 14, further supplying chemical liquids while moving a discharge opening of the etching liquid for supply, in motion relative to the upper surface of the rotating semiconductor substrate.

16. The etching method according to claim 10, wherein the processing by the etching liquid is carried out after processing of the second layer and/or the third layer by a dry etching process.

17. A method of producing a semiconductor device comprising: removing a first layer containing titanium nitride (TiN) by the etching method according to claim 10; and then producing the semiconductor device from the remaining substrate.
